(19) United States
(12) Patent Application Publication
(10) Pub. No.: US 2018/0259320 A1
(43) Pub. Date: Sep. 13, 2018

(54) FILM THICKNESS MEASUREMENT METHOD AND METHOD OF MANUFACTURING AUTOMOBILE

(71) Applicant: TOYOTA JIDOSHA KABUSHIKI KAISHA, Toyota-shi (JP)

(72) Inventors: Misato Hirayama, Toyota-shi (JP); Kinichiro Higashi, Toyota-shi (JP); Takuya Maeda, Toyota-shi (JP)

(73) Assignee: TOYOTA JIDOSHA KABUSHIKI KAISHA, Toyota-shi (JP)

(21) Appl. No.: 15/866,897

(22) Filed: Jan. 10, 2018

(30) Foreign Application Priority Data
Mar. 8, 2017 (JP) 2017-044265

(51) Int. Cl. G01B 11/06; G01B 11/14; B62D 65/00; H01L 21/304

(52) U.S. Cl. CPC G01B 11/0616; H01L 21/304; B62D 65/00; G01B 11/14

(57) ABSTRACT

A film thickness measurement method capable of measuring the film thickness of a coating film in a short period of time while maintaining the advantages of the destructive measurement method that a high measurement accuracy can be obtained are provided. A film thickness measurement method according to an embodiment is a film thickness measurement method for measuring, in a coating film 10 including a plurality of films laminated in layers, the film thickness in each of layers 1-4, the method including: a working step for performing cutting work on the coating film 10 in such a way that the coating film 10 has a predetermined gradient; and a measuring step for deriving the film thickness in each of the layers 1-4 by measuring distances of boundaries 15a-15e of the respective layers 1-4 in the coating film 10 exposed as a result of the cutting work.

### CROSS REFERENCE TO RELATED APPLICATIONS

This application is based upon and claims the benefit of priority from Japanese patent application No. 2017-044265, filed on Mar. 8, 2017, the disclosure of which is incorporated herein in its entirety by reference.

### BACKGROUND

The present invention relates to a film thickness measurement method and a method of manufacturing an automobile, and relates, for example, to a film thickness measurement method of measuring, in a coating film including a plurality of films laminated in layers, the film thickness in each of the layers, and a method of manufacturing an automobile.

The coating film of the automobile is, for example, multi-layer films, and a method of measuring the film thickness of each of the multi-layer films can be mainly divided into, for example, a destructive measurement method in which a target to be measured is measured in a destructive manner, and a non-destructive measurement method in which a target to be measured is measured in a non-destructive manner. The destructive measurement method is a method of cutting, for example, a sample out of a body to which a coating film to be measured has been applied and directly measuring the cut-out surface thereof by a magnifying microscope. On the other hand, the non-destructive measurement method is, as disclosed in, for example, Japanese Unexamined Patent Application Publication No. 2015-178980, a method of measuring the film thickness in each of the multi-layer films by analyzing interference light of reflected light when the coating film to be measured is irradiated with illumination light and reference light obtained by splitting illumination light.

In the destructive measurement method, the measurement cannot be performed for a long time since it is required to first perform grinding on a cut-out surface of the coating film as a preparation for the measurement. On the other hand, in the non-destructive measurement method, the film thickness cannot be measured unless illumination light is reflected on each of the layers of the coating film. Therefore, the coating film that can be measured is limited depending on its type. Further, since Fourier transformation and the like is required to analyze the interference light, there is a limitation in the measurement accuracy (spatial resolution). In view of these problems, a film thickness measurement method in which a high measurement accuracy can be obtained and measurement can be performed in a short period of time regardless of the type of the coating film is required.

The present invention has been made in order to solve the aforementioned problems, and aims to provide a film thickness measurement method which overcomes the above disadvantage of the destructive measurement method so that the measurement can be performed in a short period of time while maintaining the above advantages of the destructive measurement method that a high measurement accuracy can be obtained regardless of the type of the coating film.

### SUMMARY

A film thickness measurement method according to one aspect of the present invention is a film thickness measurement method for measuring, in a coating film including a plurality of films laminated in layers, the film thickness in each of the layers, the method including: a working step for performing cutting work on the coating film in such a way that the coating film has a predetermined gradient; and a measuring step for deriving the film thickness in each of the layers by measuring distances of boundaries of the respective layers in the coating film exposed as a result of the cutting work. According to the aforementioned structure, it is possible to measure the film thickness in each of the layers of the coating film in a short period of time while maintaining the advantages of the destructive measurement method that a high measurement accuracy can be obtained regardless of the type of the coating film.

Further, in the measuring step, the distances of the boundaries are measured by performing sensing using a sensor. According to the aforementioned structure, it is possible to measure the film thickness with a higher measurement accuracy.

Further, in the measuring step, when the boundaries are focused by objective lens of a microscope, the distances of the boundaries are the distances of the boundaries in a direction of an optical axis of the objective lens. According to the aforementioned structure, the film thickness can be measured by focusing the boundaries, whereby it is possible to perform measurement in a short period of time.

Further, in the measuring step, when the boundaries are focused by objective lens of a microscope, the distances of the boundaries are the distances of the boundaries when they are seen from the direction of the optical axis of the objective lens. According to the aforementioned structure, it is possible to measure the distances of the boundaries magnified on the inclined surface and to perform measurement with a high accuracy.

A method of manufacturing an automobile according to an aspect of the present invention includes the steps of: measuring the film thickness in each of the layers in the coating film including the plurality of films laminated in layers in a member of a vehicle body by the aforementioned film thickness measurement method; and repairing the part that has been subjected to cutting work to measure the film thickness. According to the aforementioned structure, it is possible to measure the film thickness of the coating film on the vehicle body in a short period of time while maintaining the advantages of the destructive measurement method that a high measurement accuracy can be obtained regardless of the type of the coating film.

According to the present invention, it is possible to provide a film thickness measurement method capable of measuring the film thickness of the coating film in a short period of time while maintaining the advantages of the destructive measurement method that a high measurement accuracy can be obtained regardless of the type of the coating film and a method of manufacturing an automobile.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF DRAWINGS

FIG. 1 is a top view illustrating a coating film measured by a film thickness measurement method according to an embodiment;

FIG. 2 is a cross-sectional view illustrating the coating film measured by the film thickness measurement method according to the embodiment and shows a cross-sectional view taken along the line AA of FIG. 1;

FIG. 3 is a flowchart illustrating an outline of the film thickness measurement method according to the embodiment;

FIG. 4 is a diagram illustrating boundaries in the film thickness measurement method according to the embodiment;

FIG. 5 is a diagram illustrating a film thickness derived from the height of objective lens on a boundary that has been measured in the film thickness measurement method according to the embodiment;

FIG. 6 is a diagram illustrating an inclined surface in a film thickness measurement method according to a modified example of the embodiment;

FIG. 7 is a flowchart illustrating the film thickness measurement method according to the embodiment;

FIG. 8 is a perspective view illustrating a sample stage on which a sample is placed in the film thickness measurement method according to the embodiment;

FIG. 9A-9C are diagrams illustrating cutting work using a drill in the film thickness measurement method according to this embodiment;

FIG. 10 is a perspective view illustrating a magnifying microscope in the film thickness measurement method according to this embodiment;

FIG. 11 is a process diagram illustrating a film thickness measurement method according to a comparative example;

FIG. 12A-12C are diagrams illustrating a sample embedded into resin in the film thickness measurement method according to the comparative example; and

FIG. 13 is a flowchart illustrating a method of manufacturing an automobile according to another embodiment.

### DESCRIPTION OF EMBODIMENTS

Hereinafter, with reference to the attached drawings, best modes for carrying out the present invention will be explained. However, the present invention is not limited to the following embodiments. Further, in order to clarify the explanation, the following descriptions and the drawings are simplified as appropriate.

### Embodiment

A film thickness measurement method according to an embodiment will be explained. The film thickness measurement method according to this embodiment is a method of measuring the film thickness in each of layers in a coating film including a plurality of films laminated in layers on a surface of, for example, a body or an element of an automobile or the like. First, a structure of the coating film, which is to be measured, will be explained.

### <Structure of Coating Film to be Measured>

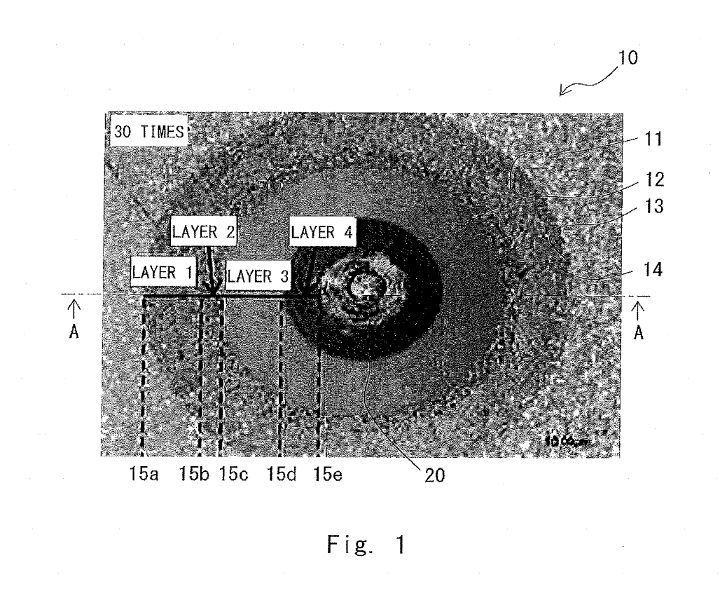

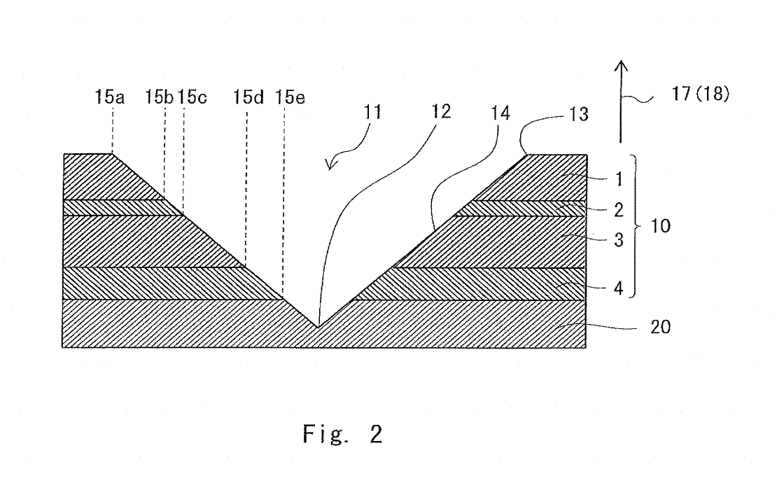

FIG. 1 is a top view illustrating a coating film measured by the film thickness measurement method according to the embodiment. FIG. 1 is a view when the coating film is observed with a magnification rate of 30 times using, for example, a magnifying microscope. FIG. 2 is a cross-sectional view illustrating the coating film measured by the film thickness measurement method according to this embodiment and shows a cross-sectional view taken along the line AA of FIG. 1. Note that the film thickness in each of the layers in the coating film shown in FIG. 2 is made larger so that the layers can be distinguished from one another.

As shown in FIGS. 1 and 2, a coating film 10 measured by the film thickness measurement method according to this embodiment includes a plurality of films laminated in layers on a base material 20. For example, films of four layers, a fourth layer 4, a third layer 3, a second layer 2, and a first layer 1 are laminated in layers on the base material 20 in this order from the layer closest to the base material 20. For example, the fourth layer 4 is formed to contact the upper surface of the base material 20 and the third layer 3 is formed to contact the upper surface of the fourth layer 4. The second layer 2 is formed to contact the upper surface of the third layer 3 and the first layer 1 is formed to contact the upper surface of the second layer 2. The number of layers of the coating film 10 is not limited to four.

The material of the base material 20 includes, for example, metal. The first layer 1 is, for example, a clear layer and the material of the first layer 1 includes, for example, resin. For example, the clear layer of the first layer 1 has a film thickness within a range from 30 to 40 μm. The second layer 2 is a metallic base layer and includes, for example, resin and metallic flakes. The metallic base layer of the second layer 2 has, for example, a film thickness of about 15 μm. The third layer 3 is an inner coated layer and includes, for example, resin. The inner coated layer of the third layer 3 has a film thickness within a range from 30 to 40 μm. The fourth layer 4 is an electrocoat layer and includes, for example, resin. The electrocoat layer of the fourth layer 4 has, for example, a film thickness within a range from 10 to 15 μm. By using the film thickness measurement method according to this embodiment, it is possible to accurately specify the film thickness in each of the layers 1-4.

As shown in FIGS. 1 and 2, a recessed part 11 that has been subjected to cutting work is formed in the coating film 10 measured by the film thickness measurement method. The recessed part 11 has a circular shape when it is seen from the lamination direction 17 of the coating film 10. The lamination direction 17 is, for example, an upward direction. A tilted inner surface 14 is formed from a bottom part 12 of the recessed part 11 to an opening 13 of the recessed part 11. Therefore, boundaries 15a-15e of the respective layers are concentrically formed when they are seen from the lamination direction 17 of the coating film 10.

The boundary 15a is formed at the periphery of the opening 13 on the surface of the first layer 1. The boundary 15b is formed between the first layer 1 and the second layer 2. The boundary 15c is formed between the second layer 2 and the third layer 3. The boundary 15d is formed between the third layer 3 and the fourth layer 4. The boundary 15e is formed between the fourth layer 4 and the base material 20. In this embodiment, the film thickness in each of the layers 1-4 is measured from the distances of the boundaries 15a-15e.

### <Outline of Film Thickness Measurement Method>

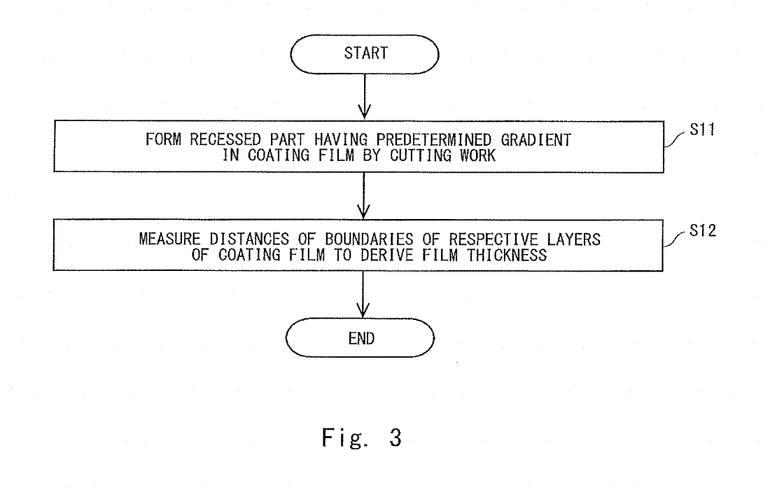

Next, an outline of the film thickness measurement method according to this embodiment will be explained. After the outline is explained, details of the film thickness measurement method will be explained. FIG. 3 is a flowchart illustrating the outline of the film thickness measurement method according to this embodiment.

First, as shown in Step S11 of FIG. 3, the recessed part 11 having a predetermined gradient is formed in the coating film 10 by cutting work (working step). The cutting work is performed using, for example, a drill. The coating film 10 is subjected to cutting work, whereby the recessed part 11 having a mortar shape is formed in the coating film 10, as shown in FIGS. 1 and 2. In this way, the coating film 10 is subjected to cutting work in such a way that the coating film 10 has a predetermined gradient. The recessed part 11 has a circular shape when it is seen from the lamination direction 17 and the base material 20 is exposed at the center of the recessed part 11. The boundaries 15a-15e of the respective layers 1-4 of the coating film 10 are exposed concentrically with the exposed base material 20 as a center thereof.

By using, for example, a drill, in the cutting work, the inner surface 14 that is tilted in a side surface shape of a cone, the cross section of the inner surface 14 having a straight line shape, can be formed. The tilted inner surface 14 is referred to as an inclined surface 19. Due to the presence of the inclined surface 19, it becomes possible to magnify and visualize the distances of the boundaries 15a-15e of the respective layers 1-4 while accurately maintaining the proportion of the distances of the boundaries 15a-15e of the respective layers 1-4. Further, by cutting work using a drill, it is possible to eliminate the preparation for the measurement of the film thickness according to the related art or dramatically reduce the process required to prepare for the measurement of the film thickness according to the related art. The preparation for the measurement of the film thickness according to the related art means, for example, performing grinding or the like on the cut-out surface of the coating film 10.

Next, as shown in Step S12 of FIG. 3, the distances of the boundaries 15a-15e of the respective layers 1-4 of the coating film 10 are measured to derive the film thickness (measuring step). The distances of the boundaries 15a-15e of the respective layers 1-4 in the coating film 10 exposed as a result of cutting work are measured by using, for example, a magnifying microscope. For example, when the boundaries 15a-15e are focused by the objective lens of the magnifying microscope, the distances of the boundaries 15a-15e in a direction of an optical axis 18 of the objective lens are measured. The optical axis 18 of the objective lens is, for example, the lamination direction 17.

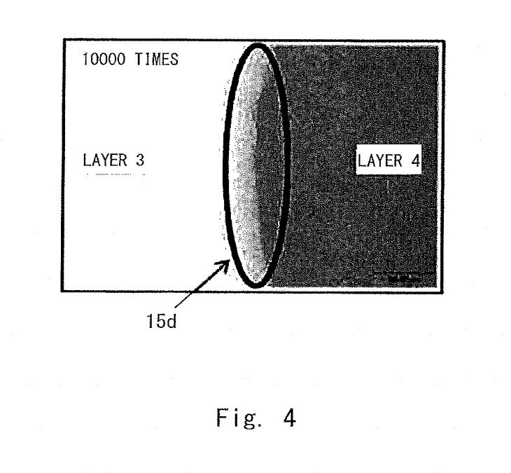

FIG. 4 is a diagram illustrating the boundary 15d between the third layer 3 and the fourth layer 4 in the film thickness measurement method according to this embodiment. FIG. 4 is a diagram when the boundary 15d is observed with a magnification rate of 1000 times using, for example, a magnifying microscope. As shown in FIG. 4, the boundary 15d between the third layer 3 and the fourth layer 4 is observed by the magnifying microscope from the lamination direction 17. The optical axis 18 of the objective lens of the magnifying microscope is adjusted in the lamination direction 17 of the coating film 10 to be measured, that is, in the direction perpendicular to the upper surface of the coating film 10. Then the distance between the objective lens and the boundary 15d is adjusted in such a way that the boundary 15d is focused by the objective lens. For example, the height of the boundary 15d is read out from the position of the objective lens when the boundary 15d is focused. Alternatively, the height of the boundary 15d is read out from the position of the boundary 15d when the boundary 15d is focused.

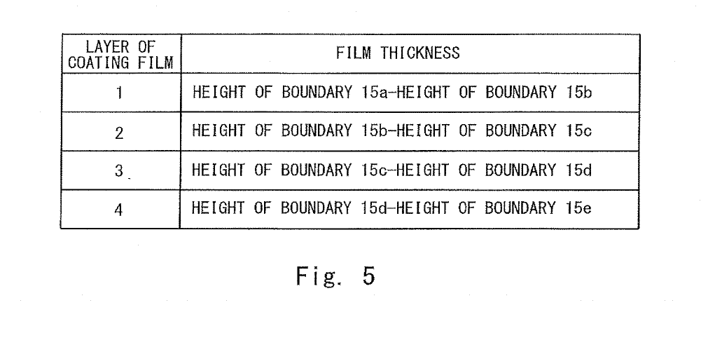

FIG. 5 is a diagram illustrating the film thickness derived from the position of the objective lens that has been measured in the film thickness measurement method according to this embodiment. As shown in FIG. 5, the film thickness of the first layer 1 can be derived from the difference between the height of the boundary 15a of the upper surface of the first layer 1 and the height of the boundary 15b between the first layer 1 and the second layer 2. The film thickness of the second layer 2 can be derived from the difference between the height of the boundary 15b between the first layer 1 and the second layer 2 and the height of the boundary 15c between the second layer 2 and the third layer 3. The film thickness of the third layer 3 can be derived from the difference between the height of the boundary 15c between the second layer 2 and the third layer 3 and the height of the boundary 15d between the third layer 3 and the fourth layer 4. The film thickness of the fourth layer 4 can be derived from the difference between the height of the boundary 15d between the third layer 3 and the fourth layer 4 and the height of the boundary 15e between the fourth layer 4 and the base material 20.

As described above, by measuring the distances of the boundaries 15a-15e of the respective layers 1-4 in the coating film 10 exposed as a result of cutting work using the magnifying microscope, the film thickness in each of the layers 1-4 can be measured. When the distances of the boundaries 15a-15e are measured, it may be measured by means other than a magnifying microscope. For example, the distances of the boundaries 15a-15e may be measured by performing sensing using a sensor such as infrared light.

### MODIFIED EXAMPLE

Next, a modified example of the embodiment will be explained.

In this embodiment, in the measuring step, when the boundaries 15a-15e are focused by the objective lens of the magnifying microscope, the distances of the boundaries 15a-15e are the distances of the boundaries 15a-15e in the direction of the optical axis 18 of the objective lens. On the other hand, in the modified example, in the measuring step, when the boundaries 15a-15e are focused by the objective lens of the magnifying microscope, the distances of the boundaries 15a-15e are the distances of the boundaries 15a-15e when they are seen from the direction of the optical axis 18 of the objective lens.

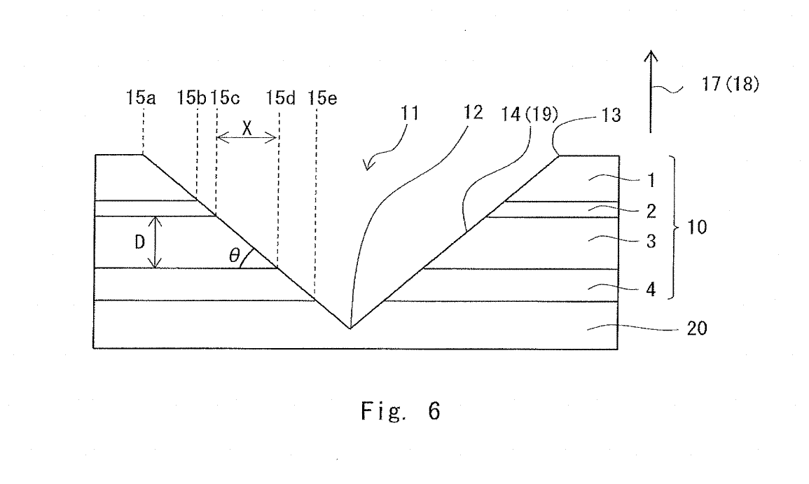

FIG. 6 is a diagram illustrating the inclined surface 19 in the film thickness measurement method according to the modified example of the embodiment. As shown in FIG. 6, the inclined surface 19 is formed from the boundary 15a to the boundary 15e. The inclined surface 19 is formed to have a predetermined angle θ with respect to the upper surface of each of the layers 1-4. The inclined surface 19 is formed by, for example, cutting work using a drill or the like.

The inclined surface 19 having a predetermined angle θ is not limited to being formed from the boundary 15a to the boundary 15e, and may be formed only in a specific part, for example, only between the boundary 15c and the boundary 15d. The way in which the inclined surface 19 is formed is not limited to cutting work using a drill. Cutting work may be performed by another method in such a way that the inclined surface 19 is formed.

The distance X of the boundaries 15a-15e when they are seen from the direction of the optical axis 18 of the objective lens is measured. Further, the angle θ of the inclined surface 19 is calculated from the drill angle, that is, the angle formed between the generatrix of the conical shape, the vertex of which being the tip of the drill formed when the drill is rotated and the upper surface of the coating film 10. The film thickness D can be derived from the following Expression (1) using the measured distance X and the calculated angle θ.

film thickness D=distance X·tan(angle θ of inclined surface) (1)

As described above, the distances of the boundaries 15a-15e of the respective layers 1-4 in the coating film 10 can be measured and the film thickness in each of the layers 1-4 can be derived. According to the modified example, it is possible to magnify the distances of the boundaries 15a-15e on the inclined surface 19 and to perform measurement with a high accuracy.

### <Details of Film Thickness Measurement Method>

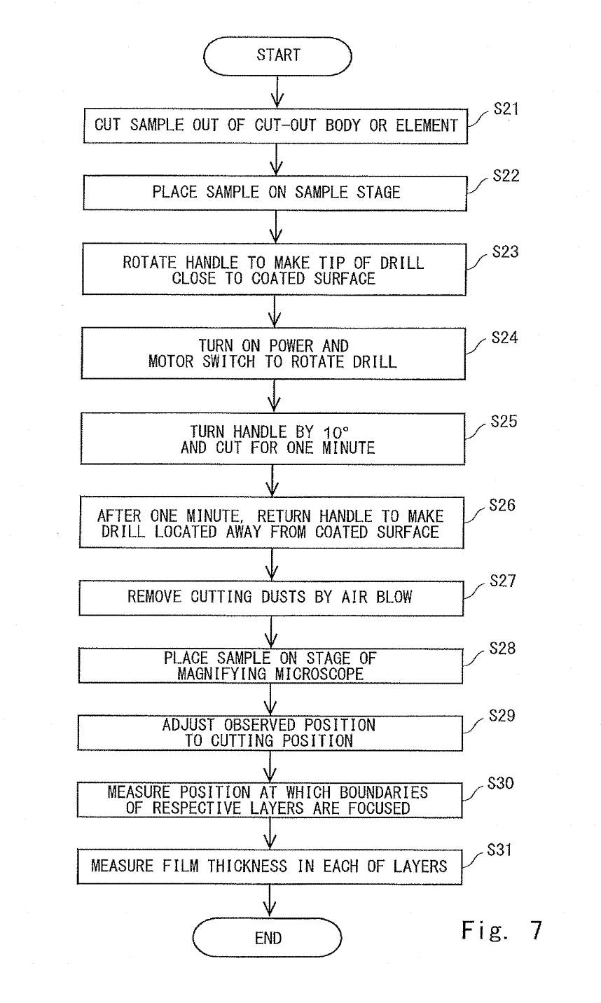

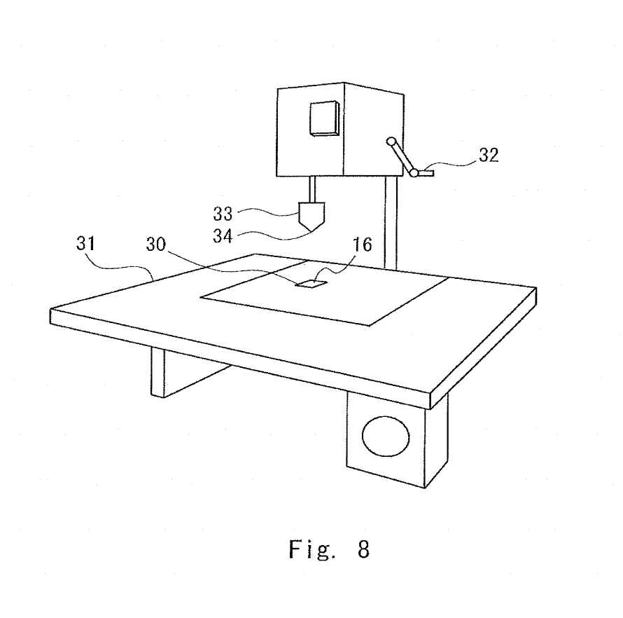

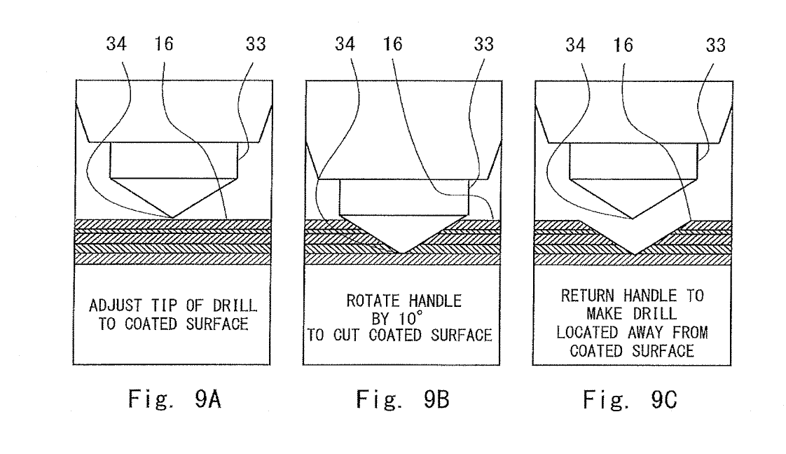

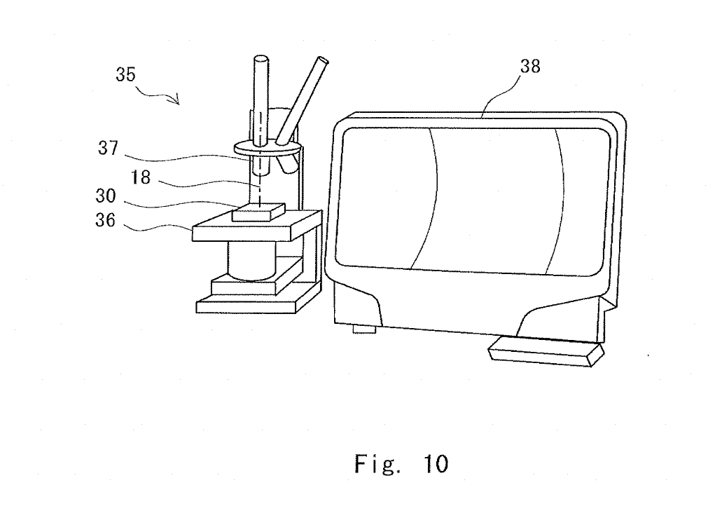

Next, details of the film thickness measurement method according to the embodiment will be explained. FIG. 7 is a flowchart illustrating the film thickness measurement method according to the embodiment. FIG. 8 is a perspective view illustrating a sample stage on which a sample is placed in the film thickness measurement method according to the embodiment. FIGS. 9A-9C are diagrams illustrating cutting work using a drill in the film thickness measurement method according to this embodiment. FIG. 10 is a perspective view illustrating the magnifying microscope in the film thickness measurement method according to this embodiment.

First, as shown in Step S21 of FIG. 7, the sample for film thickness measurement is cut out of a cut-out body cut out of the coated vehicle body or a coated element. The sample for film thickness measurement is not limited to the sample that has been cut out of the vehicle body. A part of the vehicle body of the automobile such as a hood in which the coating film 10 is formed may be directly used for the sample for film thickness measurement without cutting this part out of the vehicle body. Further, the coating film 10 whose film thickness is to be measured is not limited to being applied to the vehicle body of the automobile and may be applied to a desired object such as vehicles of any kind or home appliances of any kind.

Next, as shown in Step S22 of FIG. 7 and FIG. 8, a sample 30 is placed on a sample stage 31. Next, as shown in Step S23 of FIG. 7 and FIG. 8, a handle 32 is rotated to make a tip 34 of a drill 33 close to a coated surface 16 on which the coating film 10 is formed.

The drill 33 to be used includes, for example, tungsten carbide as a material. The drill angle is, for example, 5.7°. The drill 33 includes, for example, two blades extending from the tip to the periphery thereof to have a predetermined curved shape. The diameter of the head of the drill 33 is, for example, 5 mm. The details of the drill 33 are merely examples and may be changed as appropriate depending on the type and the thickness of the coating film 10.

Next, as shown in Step S24 of FIG. 7, the power and a motor switch of the drill 33 are turned ON to rotate the drill 33. Then, as shown in FIG. 9A, the tip 34 of the drill 33 is adjusted to the coated surface 16.

Next, as shown in Step S25 of FIG. 7 and FIG. 9B, the handle 32 is rotated, for example, by 10° and the coated surface 16 is cut. In this way, it is possible to cut the coated surface 16 using a mechanism for raising or lowering the drill 33 by operations of the handle 32. For example, the coated surface 16 is cut by the drill 33 for a minute. The number of rotations of the drill 33 is, for example, 50 rpm. The number of rotations of the drill 33, the rotation angle of the handle 32, and the cutting time are not limited thereto and optimal conditions are selected as appropriate.

Next, as shown in Step S26 of FIG. 7 and FIG. 9C, after, for example, a minute since the coated surface 16 is cut, the handle 32 is returned to make the drill 33 located away from the coated surface 16. Next, as shown in Step S27 of FIG. 7, cutting dusts generated when the coated surface 16 is cut by the drill 33 are removed by air blow.

Next, as shown in Step S28 of FIG. 7 and FIG. 10, the sample 30 is placed on a stage 36 of a magnifying microscope 35. As shown in Step S29 of FIG. 7, the observed position is adjusted to the cutting position at which the coated surface 16 is cut by the drill 33. The magnification rate of the magnifying microscope 35 can be set to, for example, 20-2000 times. It is therefore possible to measure the film thickness in each of the layers 1-4 in the coating film 10 by units of μm.

Next, as shown in Step S30 of FIG. 7, the position of objective lens 37 is adjusted so that the boundaries 15a-15e of the respective layers 1-4 are focused. The boundaries 15a-15e are focused by displaying, for example, the boundaries 15a-15e on a monitor 38. Then the position of the objective lens 37 in the direction of the optical axis 18 of the objective lens 37 is measured. In this way, the distances of the boundaries 15a-15e in the direction of the optical axis 18 of the objective lens 37 are measured. Next, the film thickness in each of the layers 1-4 is derived using the measured distances of the boundaries 15a-15e. In this way, as shown in Step S31 of FIG. 7, the film thickness in each of the layers 1-4 can be derived.

Further, when the boundaries 15a-15e are focused by the objective lens 37 of the magnifying microscope 35, the position of the objective lens 37 in the direction perpendicular to the boundaries 15a-15e when it is seen from the direction of the optical axis 18 is measured. In this way, the distances of the boundaries 15a-15e when they are seen from the direction of the optical axis 18 of the objective lens 37 are measured. In addition, the angle θ between the lower surface of each of the layers 1-4 and the inclined surface 19 is calculated. Accordingly, as shown in Step S31 of FIG. 7, the film thickness in each of the layers 1-4 can be measured.

Next, before explaining the effects of this embodiment, a comparative example will be explained. After that, the effects of this embodiment compared to the comparative example will be explained.

### COMPARATIVE EXAMPLE

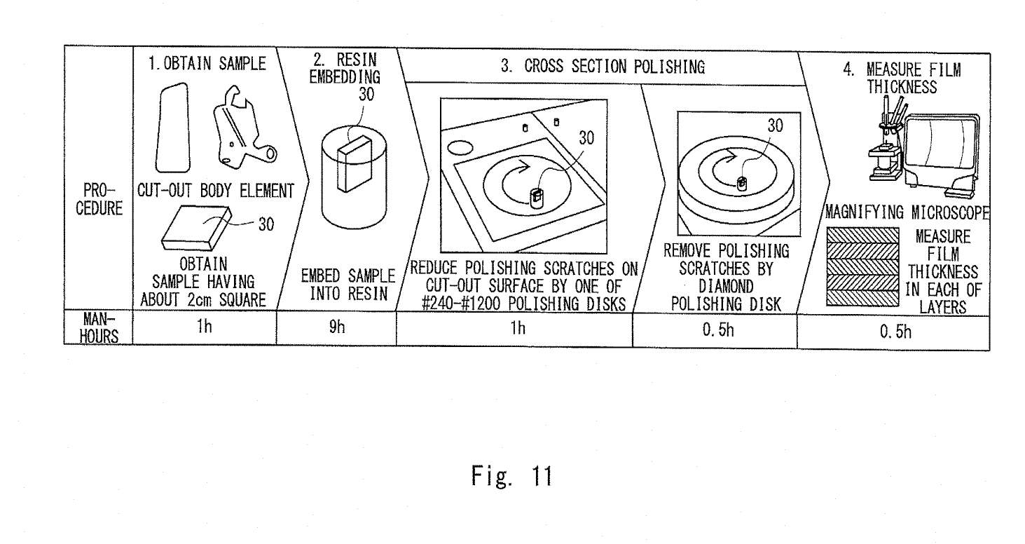

FIG. 11 is a process diagram illustrating a film thickness measurement method according to a comparative example. As shown in FIG. 11, in the film thickness measurement method according to the comparative example, first, the sample 30 is obtained (procedure 1). A cut-out body or an element is used to obtain the sample 30. The sample 30 obtained has, for example, about 2 cm square. This process takes an hour.

Next, the obtained sample 30 is embedded into resin (procedure 2). For example, the sample 30 is embedded into resin in such a way that the cut-out surface of the sample 30 is exposed. This process takes 9 hours. Next, the cut-out surface of the sample 30 is subjected to cross section polishing (procedure 3). For example, polishing scratches on the cut-out surface are reduced by one of #240-#1200 polishing disks. This process takes an hour. Further, polishing scratches are removed by a diamond polishing disk. This process takes 0.5 hours. Next, the film thickness in each of the layers 1-4 exposed on the cut-out surface is measured (procedure 4). By magnifying the cross section of each of the layers 1-4 using a magnifying microscope, the film thickness in each of the layers 1-4 is measured.

In the comparative example, it takes 12 hours from obtaining of the sample 30 (procedure 1) to measuring the film thickness (procedure 4) for each sample 30. The man-hours for 12 hours corresponds to, for example, the man-hours for 1.5 days. Therefore, in the comparative example, it takes a long time to measure the film thickness.

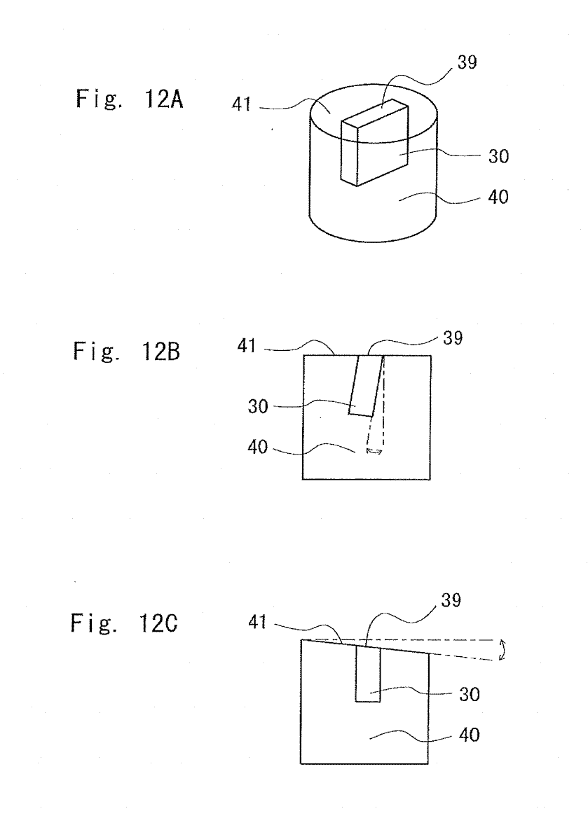

FIGS. 12A-12C are diagrams illustrating the sample 30 embedded into resin in the film thickness measurement method according to the comparative example. As shown in FIG. 12A, in the comparative example, an observed surface 41 is polished in such a way that a cut-out surface 39 is positioned on the observed surface 41 of a resin 40 that is hardened. In order to accurately measure the film thickness in each of the layers 1-4 by units of μm, the observed surface 41 needs to be made smooth by polishing. Accordingly, it is required to perform pretreatment work from obtaining of the sample 30 (procedure 1) to the cross section polishing (procedure 3) before the film thickness measurement (procedure 4) is performed.

As shown in FIG. 12B, when resin is embedded (procedure 2), the sample 30 may be tilted and the film thickness in each of the layers 1-4 in the coating film 10 may become larger than the true value. Further, as shown in FIG. 12C, when the cut-out surface is subjected to cross section polishing (procedure 3), the cut-out surface may be tilted since it cannot be evenly polished, and the film thickness in each of the layers 1-4 of the coating film 10 may become larger than the true value.

As described above, in the film thickness measurement method according to the comparative example, when the resin embedding (procedure 2) and the cross section polishing (procedure 3) are carried out, the sample 30 is tilted and the measured value becomes larger than the true value. Accordingly, it is impossible to accurately measure the film thickness. When the sample 30 is tilted by, for example, 2°, the film thickness becomes larger than the true value by no less than 3.5%.

Next, effects of this embodiment will be explained.

In the film thickness measurement method according to this embodiment, the film thickness in each of the layers 1-4 is measured by measuring the distances of the boundaries 15a-15e of the respective layers 1-4 in the coating film 10 exposed as a result of cutting work. Since there is no need to perform work from obtaining of the sample 30 (procedure 1) to the cross section polishing (procedure 3) as a preparation for the film thickness measurement like in the comparative example, it is possible to perform the measurement in a short period of time. For example, while it takes 12 hours to measure the film thickness for each sample according to the comparative example, it takes only 0.5 hours to measure the same according to this embodiment.

Further, the distances of the boundaries 15a-15e that have been exposed as a result of cutting work are measured. Accordingly, since the gradient that is generated at the time of resin embedding (procedure 2) and cross section polishing (procedure 3) in the comparative example is not generated in this embodiment, it is possible to perform measurement with a high accuracy.

Further, when the distances of the boundaries 15a-15e are measured, the position of the objective lens 37 can be specified by only focusing the boundaries 15a-15e, and the distances of the boundaries 15a-15e can be measured in a short period of time.

As described above, the film thickness measurement method according to this embodiment overcomes the disadvantage of the destructive measurement method so that the film thickness can be measured in a short period of time while maintaining the advantages of the destructive measurement method that a high measurement accuracy can be obtained regardless of the type of the coating film 10.

Further, the film thickness in each of the layers 1-4 is measured, the distances of the boundaries 15a-15e being the distances of the boundaries 15a-15e when they are seen from the direction of the optical axis 18 of the objective lens 37. Since the inclined surface 19 can be formed in the coating film 10 by cutting work in the working step, the distances of the respective layers 1-4 in the coating film 10 can be enlarged and visualized on the inclined surface 19 while maintaining the accurate proportion of the distances of the respective layers 1-4 in the coating film 10. It is therefore possible to measure the film thickness in each of the layers 1-4 with a high accuracy.

The film thickness in each of the layers 1-4 may be measured, the distances of the boundaries 15a-15e being the distances of the boundaries 15a-15e in the direction of the optical axis 18 of the objective lens 37. Even in a case in which the cross section of the inclined surface 19 formed by the cutting work is not strictly, for example, a straight line and therefore the proportion of the distances of the respective layers 1-4 in the exposed coating film 10 when it is seen from the upper surface is deviated from the proportion of the film thickness in each of the layers 1-4, it is possible to measure the film thickness in each of the layers 1-4 with a high accuracy without being affected by the deviation.

### <Method of Manufacturing Automobile>

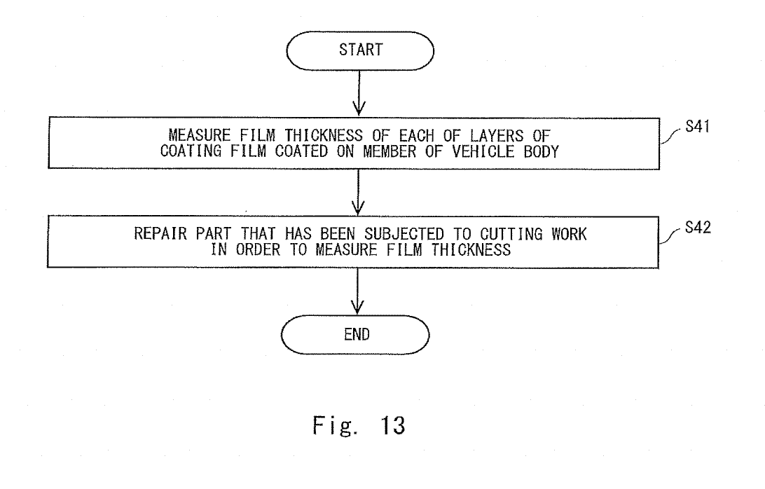

Next, as another embodiment, a method of manufacturing an automobile will be explained. The method of manufacturing the automobile according to this embodiment measures the film thickness in each of the layers 1-4 included in the coating film 10 coated on a member of a vehicle body. FIG. 13 is a flowchart illustrating the method of manufacturing the automobile according to the other embodiment.

First, as shown in Step S41 of FIG. 13, the film thickness in each of the layers 1-4 of the coating film 10 coated on a member of a vehicle body is measured. The coating film 10 includes a plurality of films laminated on a member of the vehicle body. The film thickness in each of the layers 1-4 in the coating film 10 is measured using the film thickness measurement method of the embodiment described above. The member of the vehicle body is subjected to cutting work using a drill or the like without cutting the member out of the vehicle body. For example, a hood is directly placed on the sample stage 31, and is then subjected to cutting work. Further, a part of the hood that has been subjected to cutting work is measured by the magnifying microscope 35.

Next, as shown in Step S42 of FIG. 13, the part that has been subjected to cutting work is repaired in order to measure the film thickness. Since the part that has been subjected to cutting work in this embodiment is a small area, the result of the cutting work can be made less noticeable by repairing it.

According to this embodiment, in the coating film 10 including the plurality of films laminated in layers in the member of the vehicle body, it is possible to perform measurement in a short period of time while maintaining the advantages of the destructive measurement method that it is possible to measure the film thickness in each of the layers 1-4 with a high measurement accuracy regardless of the type of the coating film 10.

While the embodiments according to the present invention have been explained above, the present invention is not limited to the aforementioned structures and the embodiments can be changed as appropriate without departing from the technical ideas of the present invention.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A film thickness measurement method for measuring, in a coating film including a plurality of films laminated in layers, the film thickness in each of the layers, the method comprising:
a working step for performing cutting work on the coating film in such a way that the coating film has a predetermined gradient; and
a measuring step for deriving the film thickness in each of the layers by measuring distances of boundaries of the respective layers in the coating film exposed as a result of the cutting work.

2. The film thickness measurement method according to claim 1, wherein, in the measuring step, the distances of the boundaries are measured by performing sensing using a sensor.

3. The film thickness measurement method according to claim 1, wherein, in the measuring step, when the boundaries are focused by objective lens of a microscope, the distances of the boundaries are the distances of the boundaries in a direction of an optical axis of the objective lens.

4. The film thickness measurement method according to claim 1, wherein, in the measuring step, when the boundaries are focused by objective lens of a microscope, the distances of the boundaries are the distances of the boundaries when they are seen from the direction of the optical axis of the objective lens.

5. A method of manufacturing an automobile comprising the steps of:
measuring the film thickness in each of the layers in the coating film including the plurality of films laminated in layers in a member of a vehicle body by the film thickness measurement method according to claim 1; and
repairing the part that has been subjected to cutting work to measure the film thickness.
